(19) United States
(12) Patent Application Publication
(10) Pub. No.: US 2014/0333719 A1
(43) Pub. Date: Nov. 13, 2014

(54) SYSTEM AND METHOD FOR PROCESSING A VERY WIDE ANGLE IMAGE

(71) Applicant: Adam Williams, Hong Kong (CN)

(72) Inventor: Adam Williams, Hong Kong (CN)

(73) Assignee: SMART EDGE INVESTMENTS LIMITED, Futian, Shenzhen, Guangdong (CN)

(21) Appl. No.: 14/342,767

(22) PCT Filed: Aug. 31, 2012
(86) PCT No.: PCT/CN2012/080885

§ 371 Date: May 4, 2014

(30) Foreign Application Priority Data
Sep. 6, 2011 (HK) HK11109422.6

(51) Int. Cl. H04N 5/225; H04N 5/232

(52) U.S. Cl. CPC H04N 5/2259; H04N 5/23238
USPC 348/36; 348/294

(57) ABSTRACT

Provided is an optical device such as a camera having an image sensor and a lens/mirror system or the like for capturing a very wide angle image such as a panoramic image and directing it towards a planar photo-sensitive surface of the image sensor. The image sensor converts the captured image, which may be a moving image, into an electrical or electronic signal or signals. The image sensor has a plurality of photo sensors or pixels arranged on a photo-sensitive surface thereof in a generally circular arrangement. The plurality of photo sensors or pixels is addressable or identifiable such that a window portion of a captured image can be defined by references to addresses or identifiers of respective photo sensors or pixels. The camera may form part of an integrated or distributed system including means for converting said electrical signal into digital image data and means for buffering or storing said digital image data. The system may also include input means for receiving a selection of a window portion of said very wide angle image and means for retrieving digital image data comprising said selected window portion from said buffer or storage means and transmitting said retrieved digital image data to an information processing means for display and/or further processing. An image projection system is also disclosed sharing mans of the novel technical features of the camera.

### TECHNICAL FIELD

The invention relates to a system and method for processing a very wide angle still and/or moving image.

### BACKGROUND ART

The field of view or image view captured by a camera is determined by the lens of the camera at the location of interest. In the case of surveillance systems, for example, using one or more conventional type camera units such as CCTV units, it is necessary to control the camera unit to pan and/or tilt in order to change the image view to explore and perhaps record images from the environment surrounding the camera unit that were not previously within its field of view. Panning and tilting of such a camera unit normally requires the camera unit to be fitted with motors and to have some means of receiving control signals to control the motors to effect panning and tilting actions. Furthermore, the motors require a power supply which is often of a different specification to that required by the camera unit for camera operation.

In such systems as surveillance systems, the camera units as described above are relatively complex with many mechanical moving parts. As such, the camera units require regular maintenance. However, the difficulty of providing maintenance is exacerbated by the fact that the units are often located at positions deliberately selected as not being easy to access. Furthermore, the camera units are often housed in sealed security housings which, partly due to the power consumption by the motors for effecting panning and tilting, results in overheating which is not desirable. An undesirable consequence of overheating can be distortion of the image scene viewed by the camera unit. Also, conventional camera units with motor effected tilting and panning functions are expensive to manufacture. With such camera units, if an event occurs outside the field of view of the camera, it is ‘lost’ in that it is not seen and thus not recorded.

In environments where constant 360 degree surveillance of an area is required or desirable, it is often necessary to deploy multiple conventional camera units pointed in different directions to cover respective different parts of the area of interest thereby significantly increasing the cost of the surveillance system. Furthermore, even with multiple camera units covering overlapping areas, blind spots often still exist.

Some 360 degree panoramic image capturing camera units have been developed using solid state image recording means. One reason why this type of camera unit is not currently favoured in surveillance systems or the like is that the recorded panoramic image is recorded in a severely distorted format as a consequence of the manner by which the 360 degree panoramic image scene is captured and they recorded by the solid state image recording means. In camera units of this type, powerful information processing means are normally required to correct image distortion prior to viewing resulting in loss of picture quality and greatly increasing the cost of such systems.

In the case of projecting an image onto a screen, the conventional arrangement is to project a still or moving planar image onto a planar screen. Conventional projectors therefore are normally arranged with a simple focusing lens that is adapted to focus the projected image onto a planar surface of the screen. Such projectors are not adapted to projecting full or partial panoramic images, i.e. non-planar images adapted to be viewed on non-planar screens.

### DISCLOSURE OF INVENTION

### Technical Problem

An object of the invention is to mitigate or obviate to some degree one or more problems associated with known systems, cameras, projectors and methods of processing very wide angle still and/or moving images.

The above object is met by the combination of features of the main claims; the subclaims disclose further advantageous embodiments of the invention.

Another object of the invention is to mitigate or obviate to some degree one or more problems associated with known systems, cameras and methods for capturing surveillance images or the like.

Another object of the invention is to provide a system for capturing, recording, distributing and/or projecting still and/or moving panoramic images.

Another object of the invention is to provide a camera and/or projector unit for processing very wide angle still and/or moving images.

Another object of the invention is to enable users to select for viewing defined window portions of a panoramic image for display on conventional rectilinear display devices.

One skilled in the art will derive from the following description other objects of the invention. Therefore, the foregoing statements of object are not exhaustive and serve merely to illustrate some of the many objects of the present invention.

### SOLUTION TO PROBLEM

### Technical Solution

In one aspect, the invention provides an image sensor for an optical device, said image sensor comprising: a planar photo-sensitive surface comprising a plurality of photo sensors or pixels positioned on said planar photo-sensitive surface in a generally circular arrangement for converting an image incident thereon into an electrical or electronic signal or signals.

The plurality of photo sensors or pixels may be arranged on said planar photo-sensitive surface as a series of concentric circles. Alternatively, there may be arranged on said planar photo-sensitive surface in said generally circular arrangement comprising at least one spiral line of photo sensors or pixels. The plurality of photo sensors or pixels may be arranged as two or more interlaced spiral lines of photo sensors or pixels.

The image sensor may comprise means such as a lens/mirror system or the like for capturing a very wide angle image and directing it towards said planar photo-sensitive surface to be incident on said plurality of photo sensors or pixels. The means for capturing a very wide angle image may be arranged to capture a substantially panoramic image surrounding the image senor. The substantially panoramic image may not be a full panoramic image, but may comprise a 360 degree doughnut shaped image view in a selected plane about the image sensor. Alternatively, the substantially panoramic image may be a full panoramic image comprising a generally hemispherical image view about the image capturing means.

The image sensor may further comprise: means for converting said electronic or electrical signal or signals into digital image data.

The plurality of photo sensors or pixels may be addressable or identifiable such that a window portion of a captured image can be defined by reference to addresses of respective photo sensors or pixels.

In some embodiments, the optical device comprises a camera or a projector.

In a further aspect of the invention, there is provided a method of capturing a very wide angle image using an image sensor for an optical device, said method comprising: directing a very wide angle image onto a photo-sensitive surface of said image sensor, said image sensor comprising a planar photo-sensitive surface having a plurality of photo sensors or pixels positioned on said planar photo-sensitive surface in a generally circular arrangement.

In another aspect of the invention, there is provided a method of manufacturing an image sensor for an optical device, said method comprising: providing an image sensor with as planar photo-sensitive surface having a plurality of photo sensors or pixels positioned on said planar photo-sensitive surface in a generally circular arrangement.

In yet another aspect of the invention, there is provided an image sensor for an optical device, said image sensor comprising: a photo-sensitive surface comprising a plurality of photo sensors or pixels positioned on said photo-sensitive surface for convening a very wide angle image or a portion thereof incident thereon into electrical or electronic signal or signals convertible to image data representative of said very wide angle image or said portion thereof, the arrangement being such that the photo sensors or pixels are each orientated on said photo-sensitive surface in a direction generally coincident with a respective part of said very wide angle image incident thereon.

In yet a further aspect of the invention, there is provided a method of capturing a very wide angle image using an image sensor for an optical device, said method comprising: directing a very wide angle image on to a photo-sensitive surface of said image sensor, said image sensor comprising a photo-sensitive surface having a plurality of photo sensors or pixels positioned on said photo-sensitive surface for converting, said very wide angle image or a portion thereof incident thereon into electrical or electronic signal or signals convertible to image data representative of said very wide angle image or said portion thereof, the arrangement being such that the photo sensors or pixels are each orientated on said photo-sensitive surface in a direction generally coincident with a respective part of said very wide angle image incident thereon.

In a yet further aspect of the invention, the invention provides a camera having an image sensor and a lens/mirror system or the like for capturing a very wide angle image such as a panoramic image and directing it towards a planar photo-sensitive surface of the image sensor. The image sensor converts the captured image, which may be a moving image, into an electrical or electronic signal or signals. The image sensor has a plurality of photo sensors or pixels arranged on a photo-sensitive surface thereof in a generally circular arrangement. The generally circular arrangement may comprise a tight spiral of photo sensors or pixels. The plurality of photo sensors or pixels is addressable or identifiable such that a window portion of a captured image can be defined by references to addresses or identifiers of respective photo sensors or pixels. The camera may form part of an integrated or distributed system including means for converting said electrical signal into digital image data and means for buffering or storing said digital image data. The system may also include input means for receiving a selection of a window portion of said very wide angle image and means for retrieving digital image data comprising said selected window portion from said buffer or storage means and transmitting said retrieved digital image data to an information processing means for display and/or further processing.

In a first main aspect of the invention, there is provided a system for capturing and recording a very wide angle image, comprising: means for capturing a very wide angle image and directing it towards a planar photo-sensitive surface of an image sensor, said image sensor converting said very wide angle image into an electrical signal; means for converting said electrical signal into digital image data; means for buffering or storing said digital image data; means for receiving a selection of a window portion of said very wide angle image; and means for retrieving digital image data comprising said selected window portion of said very wide angle image from said buffer or storage means and transmitting said retrieved digital image data to an information processing means. The system may be an integrated system comprising a single apparatus such as a camera unit and associated processing capabilities or it may comprise a distributed system comprising a number of apparatuses connected by a network.

The system may be arranged to capture still images in the manner of a stills images camera, but preferably it is arranged to capture moving images, although it preferable that it will also retain a still images capacity.

The system includes processing means or the like for converting a captured moving or still image into a digital video signal or into any other form of signal for distribution over a network in response to user requests/selections.

The means for capturing a very wide angle image and directing it towards a photo-sensitive surface of an image sensor may comprise any suitable system or arrangement known to the skilled artisan for capturing a wide angle image. For example, the image capturing means may comprise any one or any combination of: a lens, a set of lenses, a mirror, a set of mirrors, a prism, or a set of prisms. In some embodiments, the image capturing means comprises a fish-eye lens.

Preferably, the image capturing means is arranged to capture a substantially panoramic image surrounding the image capturing means. The substantially panoramic image may not be a full panoramic image, but may comprise a 360 degree doughnut shaped image view in a selected plane about the image capturing means. Or, the substantially panoramic image may be a full panoramic image comprising a generally hemispherical image view about the image capturing means.

The image sensor may comprise an image sensor chip having a photo-sensitive surface comprising a plurality of photo sensors or pixels for converting incident light into electrical signals. A number of such chips are known such as a charge-coupled device (CCD) chip and a complementary metal oxide semiconductor (CMOS) chip. However, as will be apparent to a skilled artisan, any chip suitable for converting a captured image incident on a photo-sensitive surface of the chip into an electrical signal or signals can be employed in the system and camera unit of the invention.

The plurality of photo sensors or pixels is arranged on said photo-sensitive surface in a generally circular arrangement.

In one embodiment the plurality of photo sensors or pixels may be arranged on said photo-sensitive surface as a series of concentric circles. In this embodiment, alternate ones of said series of concentric circles of photo sensors or pixels may be respectively assigned to odd and even lines of a digital video signal.

In another embodiment, the plurality of photo sensors or pixels may be arranged on said photo-sensitive surface as at least one tight spiral line of photo sensors or pixels or the plurality of photo sensors or pixels may be arranged as two or more interlaced spiral lines of photo sensors or pixels. The arrangement may be such that said spiral line or interlaced lines of photo sensors or pixels fills the surface of the photo-sensitive surface without leaving any gaps between said photo sensors or pixels.

Preferably, the means for receiving a selection of a window portion of said very wide angle image is adapted to receive commands associated with said selected window portion such as to pail command, a tilt command and/or a zoom in or out command.

Preferably, the means for receiving a selection of a window portion of said very wide angle image is adapted to receive two or more separate selections of respective window portions of said very wide angle image at the same time. These selections may be from different users and the respective image data for the selected window portions transmitted to information processing apparatuses of said users for viewing and further processing. The selected window portions may be the same, different or overlapping, the selections preferably being independent of one another.

Any suitable storage or buffering means familiar to a skilled artisan may be used for buffering and/or storing the digital image data for the captured stills and/or moving images. For example, the means for buffering or storing said digital image data may comprise a flash memory device or it may comprise a database or memory bank or the like connected to said image capturing means via a network. The means for buffering and/or storing said digital image data may comprise part of a same device as the image capturing means as in a camera unit, for example. Alternatively, the means for buffering and/or storing said digital image data may comprise part of a different device than that comprising the image capturing means. In this latter instance, the different device comprising said means for buffering and/or storing said digital image data is connected via a network to said device comprising said image capturing means.

In a similar vein, the means for receiving a selection of a window portion of said very wide angle image may comprise a part of a same device as the means for buffering and/or storing said digital image data, said selection means comprising in one embodiment an input screen of a camera unit, for example. Alternatively, the selection means may comprise a part of a different device than that comprising the storage/buffering means and, in this case, the different device comprising said selection means is connected via a network to said device comprising said storage/buffering means.

Also, the means for retrieving digital image data comprising said selected window portion of said very wide angle image may comprise a part of a same device as the storage/buffering means or it may comprise part of a different device where said different device is a networked device.

In similar manner, the information processing means may comprise part of a same or a different device to the storage/buffering means, where said different device is a networked device.

Preferably, the information processing means is arranged to provide said selection of a window portion of said very wide angle image.

The means for receiving a selection of a window portion of said very wide angle image may comprise a suitably configured server for receiving user selections. The server may be connected to said image capturing means via a network. Similarly, the means for retrieving digital image data comprising said selected window portion may comprise a server for receiving user selections and said server may be connected to said image capturing means via a network. The server for receiving a window selection and the server for retrieving digital image data may be one and the same server.

In a second main aspect of the invention, there is provided a method of capturing and recording a very wide angle image, comprising the steps of: capturing a very wide angle image and directing it towards a planar photo-sensitive surface of an image sensor; converting said captured very wide angle image into an electrical signal; converting said electrical signal into digital image data; buffering or storing said digital image data; receiving a selection of a window portion of said very wide angle image; retrieving digital image data comprising said selected window portion of said very wide angle image from said buffer or storage means; and transmitting said retrieved digital image data to an information processing means.

In a third main aspect of the invention, there is provided a camera comprising: an image sensor; and means for capturing a very wide angle image and directing it towards a planar photo-sensitive surface of said image sensor, said image sensor converting said very wide angle image into an electrical signal; wherein a plurality of photo sensors or pixels of said image sensor is arranged on a photo-sensitive surface of said image sensor in a generally circular arrangement, and wherein said plurality of photo sensors or pixels are addressable such that a window portion of a captured image can be defined by references to addresses of respective photo sensors or pixels.

In a fourth main aspect of the invention, there is provided an image sensor for a camera unit, said image sensor comprising: a planar photo-sensitive surface of said image sensor for converting an image incident thereon into an electrical signal; wherein said photo-sensitive surface comprises a plurality of photo sensors or pixels in a generally circular arrangement and wherein said plurality of photo sensors or pixels are addressable such that a window portion of a captured image can be defined by reference to addresses of respective photo sensors or pixels.

In a fifth main aspect, the invention provides a system for projecting a very wide angle image onto a viewing surface, comprising: means for receiving very wide angle image data; means for converting said very wide angle image data to an optical image and for directing said optical image or a portion of said optical image towards an image projection means; a viewing surface mounted in proximity to said image projection means; wherein said image projection means projects said optical image or a portion of said optical image onto said viewing surface; and wherein said means for converting said very wide angle image data to said optical image comprises a plurality of photo sensors or pixels for converting received image data into said optical image, said plurality of photo sensors or pixels being arranged in a generally circular arrangement.

Preferably, the plurality of photo sensors or pixels is arranged in a series of concentric circles. Alternate ones of said series of concentric circles of photo sensors or pixels may be respectively assigned to odd and even lines of a digital video signal embodied in said very wide angle image data.

Alternatively, the plurality of photo sensors or pixels may be arranged as at least one spiral line of photo sensors or pixels. The plurality of photo sensors or pixels are preferably arranged as two or more interlaced spiral lines of photo sensors or pixels.

Preferably, the plurality of photo sensors or pixels are embodied in a LED display panel, a LED display panel or an integrated circuit comprising light emitting pixels or photo sensors.

The image projection means may comprise a lens, a set of lenses, a mirror, a set of mirrors, a prism, or a set of prisms for projecting the optical image generated by said plurality of photo sensors or pixels.

The system may include a means for receiving a selection of a window portion of said very wide angle optical image.

The system may also include means for retrieving digital image data comprising said selected window portion of said very wide angle optical image from buffer or storage means.

The system may comprise a heads-up display in a headgear worn by a user and the viewing surface may comprise a visor of the headgear and the system may be arranged to receive a selection of a window portion of said very wide angle optical image in response to movement of the person's head and thus the headgear relative to a predetermined datum.

Preferably, the projection means comprises a fish-eye lens.

Preferably, the means for converting is arranged to convert said received image data into a substantially panoramic optical image for projection of said panoramic image or a portion of such image onto the viewing surface. The viewing surface may be a panoramic viewing surface surrounding the projection means and the projection means may be arranged to project the panoramic image onto said panoramic viewing surface. The panoramic image may not be a full panoramic image, but comprises a 360 degree doughnut shaped image view in a selected plane about the projection means. Alternatively, the panoramic image may be a full panoramic image comprising a generally hemispherical image view about the projection means.

The means for receiving a selection of a window portion of said very wide angle image may be adapted to receive commands associated with said selected window portion such as any of a pan command, a tilt command and a zoom command. The means for receiving a selection of a window portion of said very wide angle image may be adapted to receive two or more separate selections of respective window portions of said very wide angle optical image at the same time.

The means for buffering or storing said digital image data may comprise part of a same device as the image projection means for projecting said optical image or a portion of said optical image onto said viewing surface. Alternatively, the means for buffering or storing said digital image data may comprise part of a different device than that comprising the means for projecting said optical image or a portion of said optical image onto said viewing surface. The different device comprising said means for buffering or storing said digital image data may be connected via a network to said device comprising said means for projecting said optical image or a portion of said optical image onto said viewing surface.

The means for receiving a selection of a window portion of said very wide angle image may comprise a part of a same device as the means for buffering or storing said digital image data. Alternatively, the means for receiving a selection of a window portion of said very wide angle image may comprise a part of a different device than that comprising the means for buffering or storing said digital image data. The different device comprising said means for receiving a selection of a window portion of said very wide angle image may be connected via a network to said device comprising said means for buffering or storing said digital image data.

The means for retrieving digital image data comprising said selected window portion of said very wide angle image may comprise a part of as same device as the means for buffering or storing said digital image data. Alternatively the means for retrieving digital image data comprising said selected window portion of said very wide angle image may comprise a part of a different device than that comprising the means for buffering or storing said digital image data. The different device comprising said means for retrieving digital image data comprising said selected window portion of said very wide angle image may be connected via as network to said device comprising said means for buffering or storing said digital image data.

Preferably, the means for buffering or storing said digital image data comprises as flash memory device. Alternatively, the means for buffering or storing said digital image data may comprise a database connected to said image projection means via a network.

The means for receiving a selection of a window portion of said very wide angle image may comprise a server for receiving user selections of window portions of said very wide angle optical image, said server being connected to said means for projecting the very wide angle image via a network.

The means for retrieving digital image data comprising said selected window portion of said very wide angle optical image may comprise a server for receiving user selections of window portions of said very wide angle image, said server being connected to said means for projecting the very wide angle image via a network.

In a sixth main aspect of the invention, the is provided a method of projecting a very wide angle image onto a viewing surface, comprising: receiving very wide angle image data converting said very wide angle image data to an optical image using a plurality of photo sensors or pixels for converting received image data into said optical image, said plurality of photo sensors or pixels being arranged in a generally circular arrangement; directing said optical image or a portion of said optical image towards an image projection means; and projecting said optical image or a portion of said optical image onto a viewing surface mounted in proximity to said image projection means.

In a seventh main aspect of the invention, there is provided a projector for projecting a very wide angle image onto a viewing surface, comprising: an input for receiving very wide angle image data; means for converting said very wide angle image data to an optical image and for directing said optical image or a portion of said optical image towards an image projection means; wherein said image projection means projects said optical image or a portion of said optical image onto a viewing surface mounted in proximity to said image projection means; and wherein said means for converting said very wide angle image data to said optical image comprises a plurality of photo sensors or pixels for converting received image data into said optical image, said plurality of photo sensors or pixels being arranged in a generally circular arrangement.

In an eighth main aspect of the invention, there is provided a heads-up display in a headgear worn by a user, comprising: a viewing surface comprising a visor of the headgear; and the projector of the seventh main aspect for projecting an optical image or a portion of said optical image a surface of said visor.

Preferably, the head-up display further comprises means for receiving a selection of a window portion of said very wide angle optical image in response to movement of the person's head and thus the headgear relative to a predetermined datum.

In an ninth main aspect of the invention, there is provided a conference call system wherein at least one participant conference station includes a projector of the seventh main aspect of the invention.

The summary of the invention does not necessarily disclose all the features essential for defining the invention; the invention may reside in a sub-combination of the disclosed features.

### BRIEF DESCRIPTION OF DRAWINGS

### Description of Drawings

The foregoing and further features of the present invention will be apparent from the following description of preferred embodiments which are provided by way of example only in connection with the accompanying figures, of which:

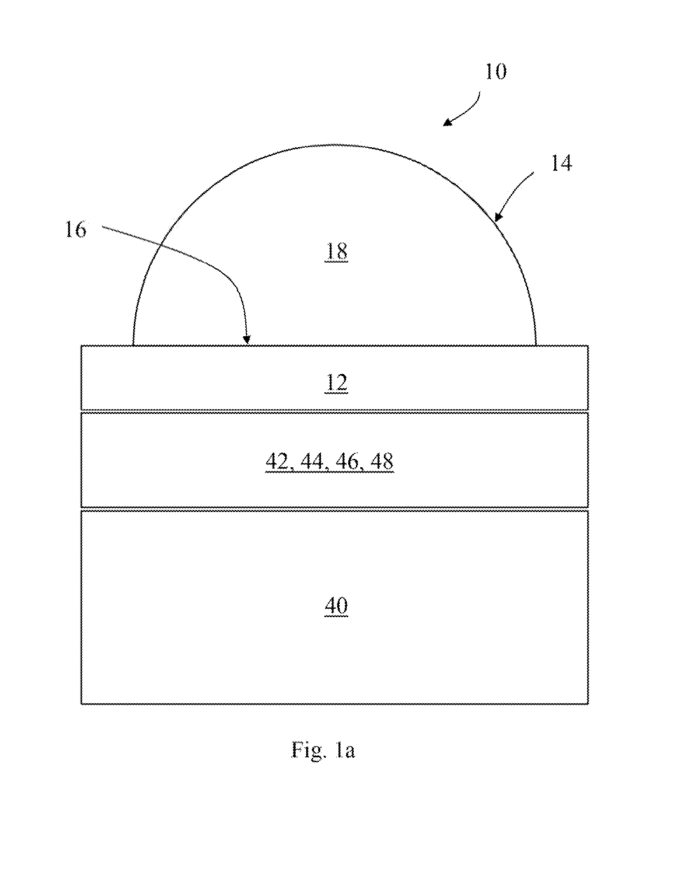

FIGS. 1a and 1b are respectively a side view and a plan view of a camera system according to the invention for capturing a panoramic image;

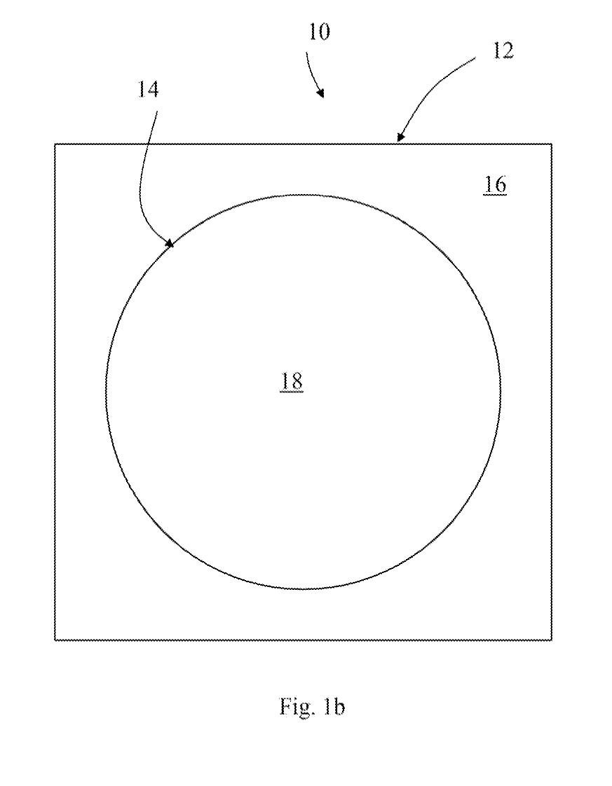

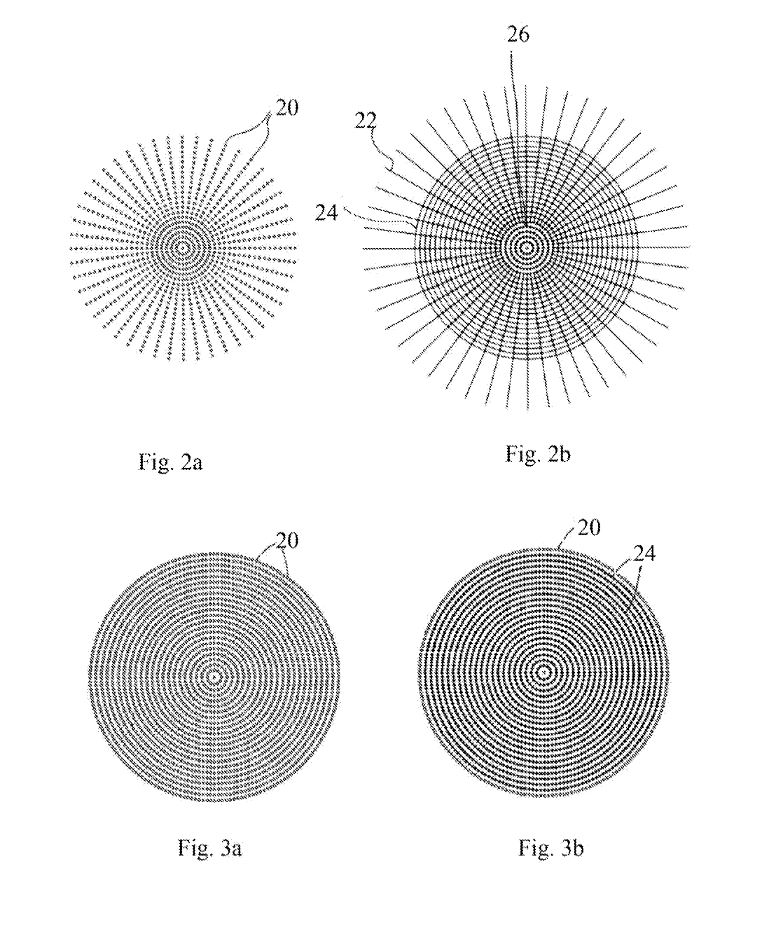

FIGS. 2a and 2b are respective plan views of one embodiment of a photo sensor or pixel arrangement of an image sensor chip for the system of FIG. 1;

FIGS. 3a and 3b are respective plan views of another embodiment of a photo sensor or pixel arrangement of an image sensor chip for the system of FIG. 1;

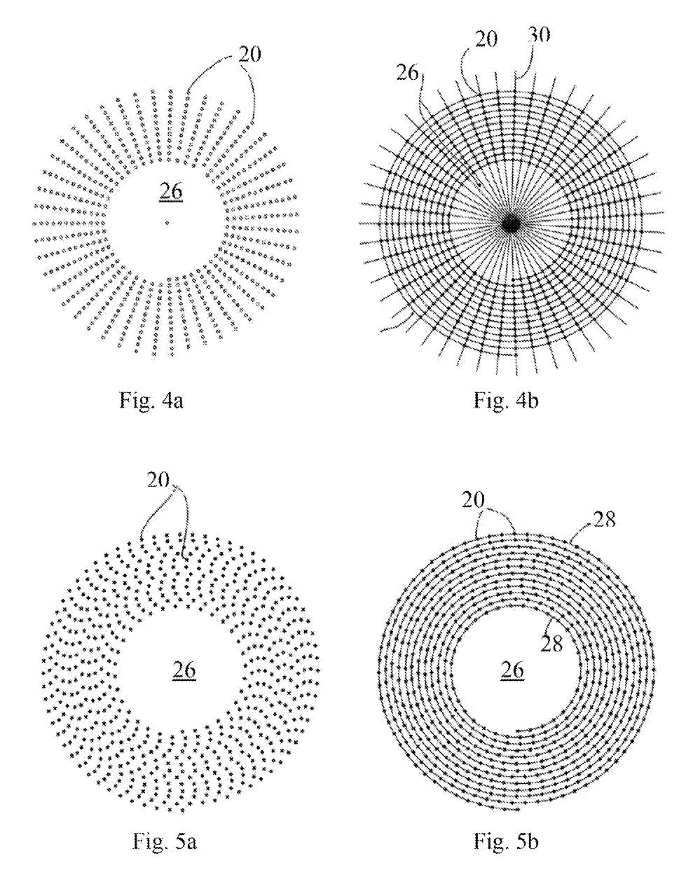

FIGS. 4a and 4b are respective plan views of yet another embodiment of a photo sensor or pixel arrangement of an image sensor chip for the system of FIG. 1;

FIGS. 5a and 5b are respective plan views of yet another embodiment of a photo sensor or pixel arrangement of an image sensor chip for the system of FIG. 1.

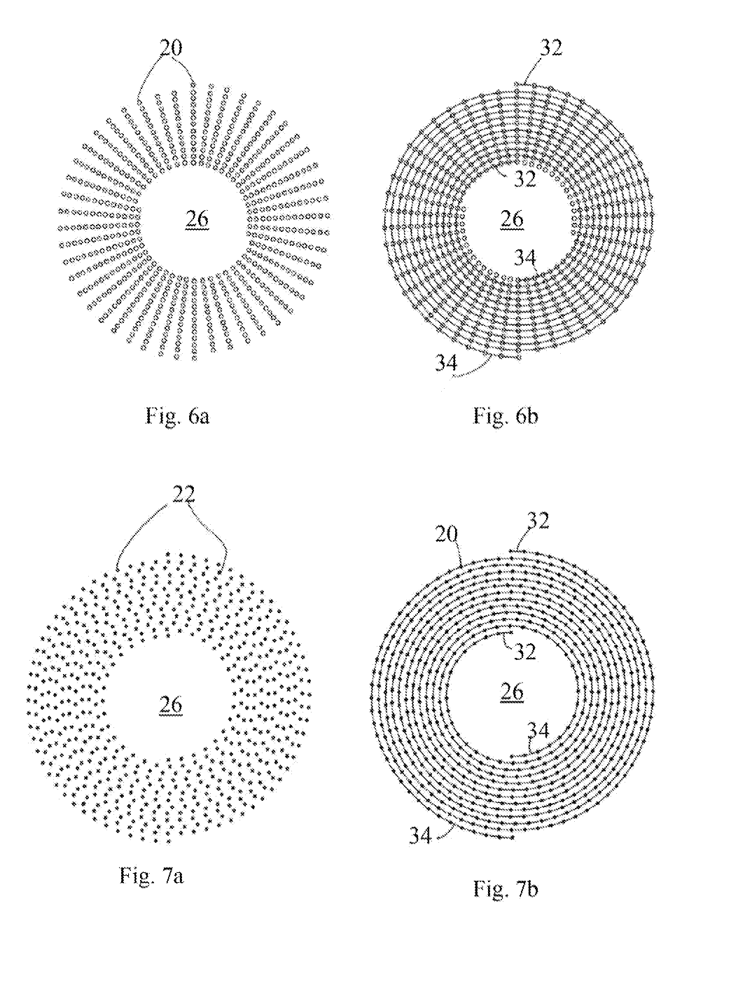

FIGS. 6a and 6b are respective plan views of yet another embodiment of a photo sensor or pixel arrangement of an image sensor chip for the system of FIG. 1;

FIGS. 7a and 7b are respective plan views of yet another embodiment of a photo sensor or pixel arrangement of an image sensor chip for the system of FIG. 1;

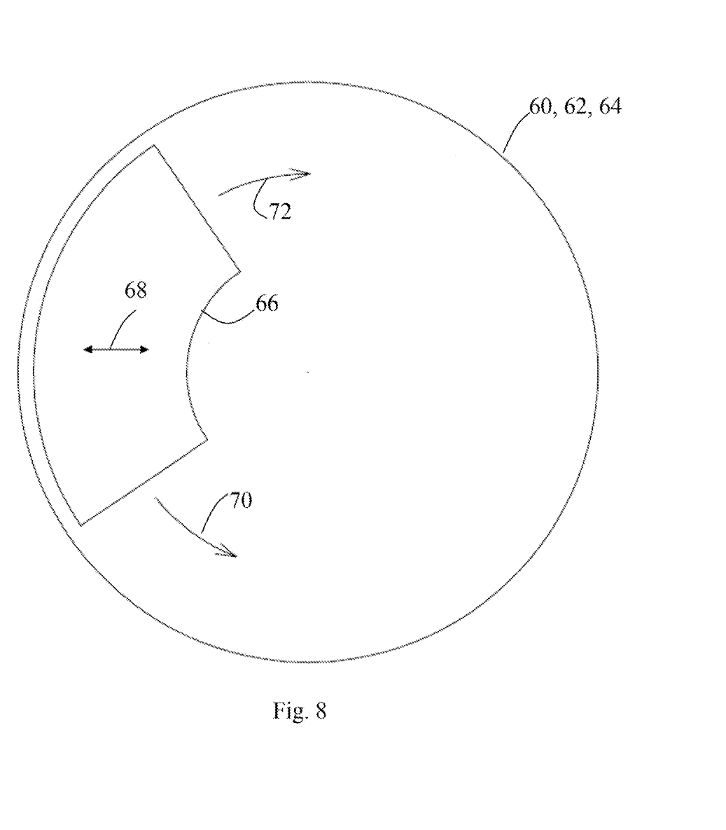

FIG. 8 is a plan view of a device display image of the panoramic image or a representative image of the panoramic image with a window frame overlying said display image to enable a user to make a selection of a window portion for viewing;

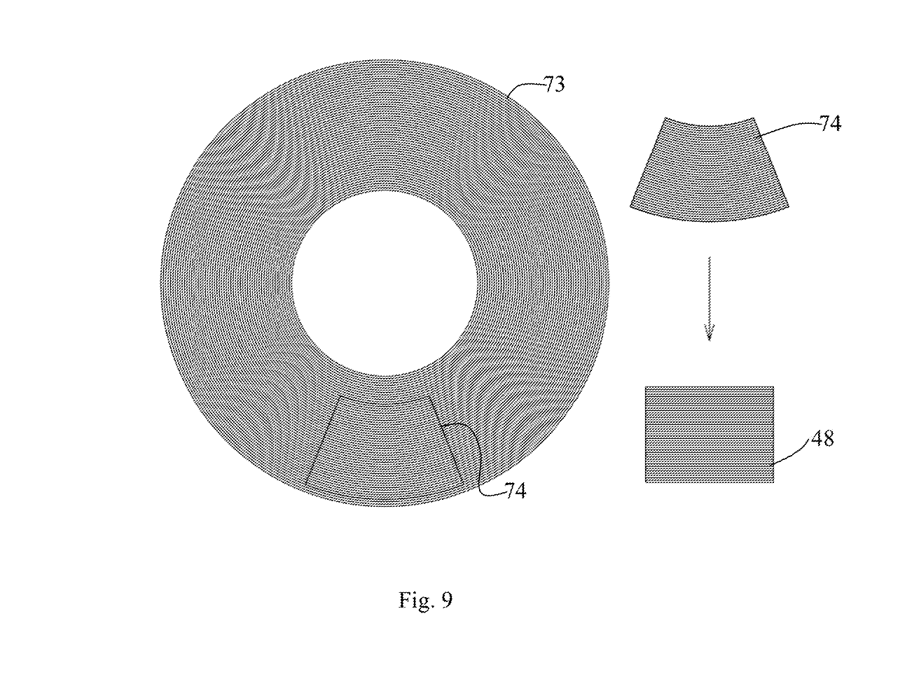

FIG. 9 is a plan view of a photo sensor or pixel arrangement showing a relationship between a selected window portion of the panoramic image and a displayed image of said selected window portion on a monitor or display of a device;

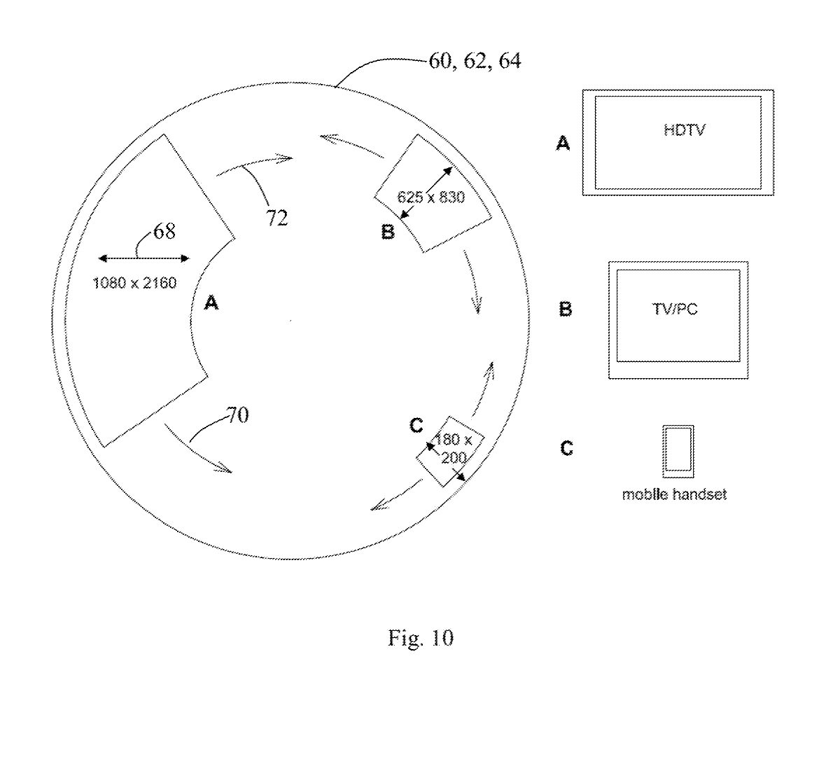

FIG. 10 is a plan view a device display image of the panoramic image or a representative image at the panoramic image with multiple window frames overlying said display image to enable a user to make a selection of a window portion of a predefined aspect ratio for viewing;

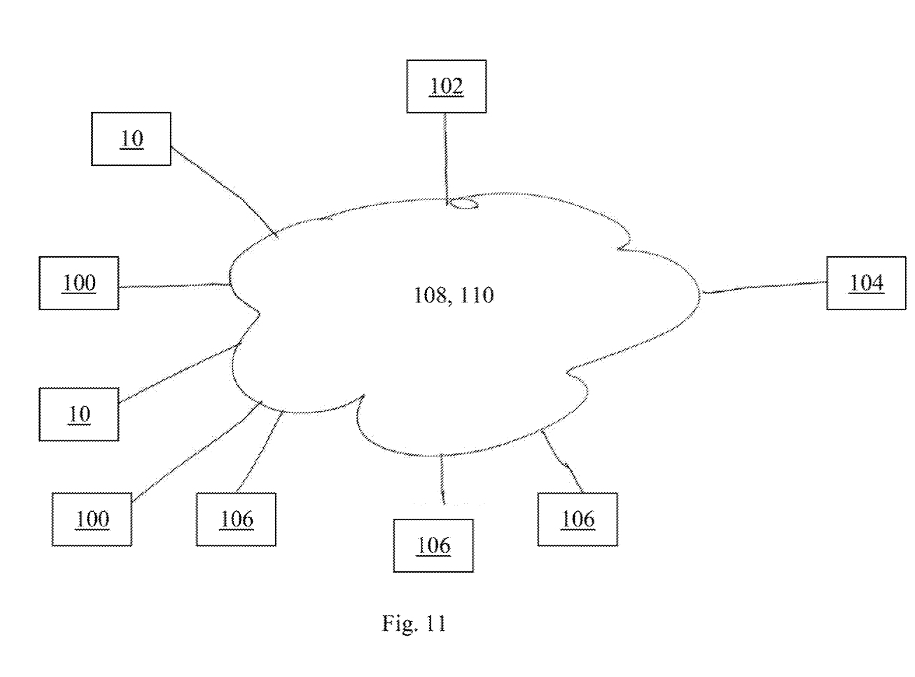

FIG. 11 is a schematic diagram of a distributed network system including a camera system of the invention and a projector system of the invention for outputting digital image data to one or more separate devices;

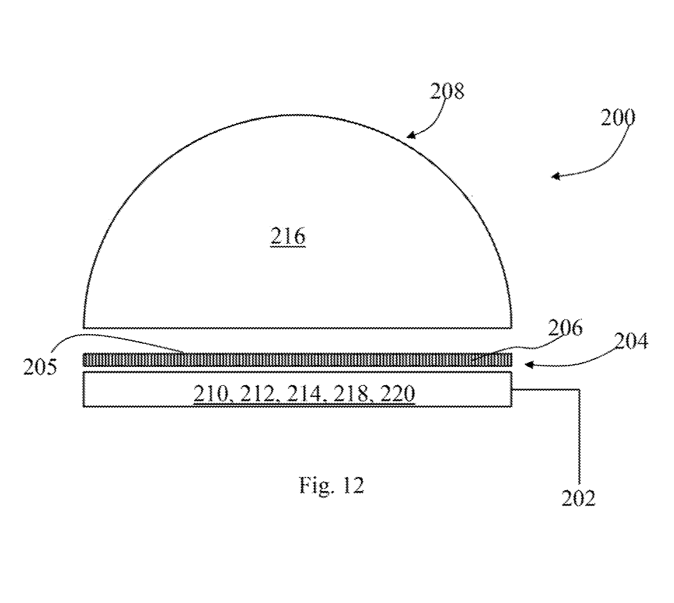

FIG. 12 is a side view of a first embodiment of a projector system according to the invention;

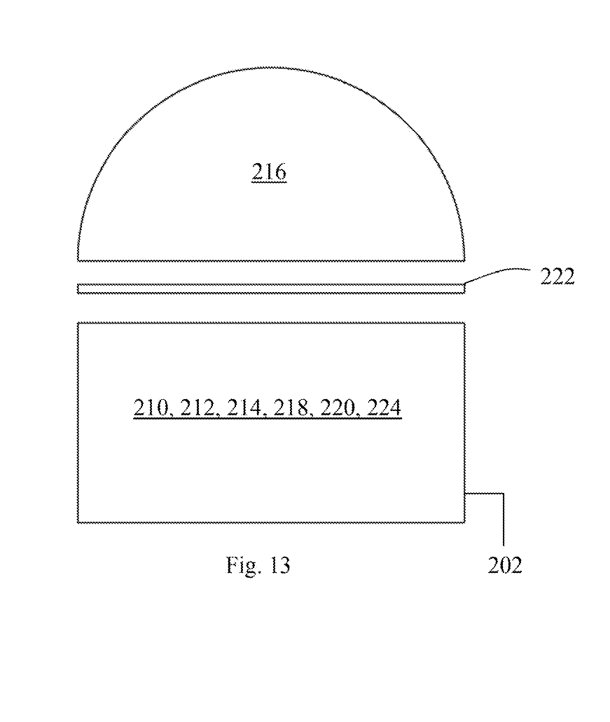

FIG. 13 is a side view of a second embodiment of a projector system according to the invention;

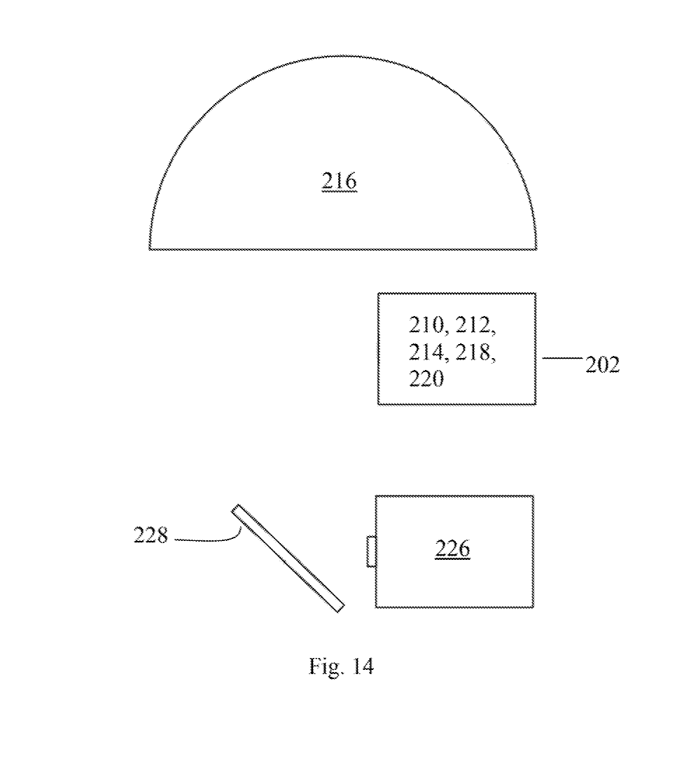

FIG. 14 is a side view of a third embodiment of a projector system according to the invention;

FIG. 15 illustrates a projector unit of any of FIGS. 12 to 14 positioned for projecting a panoramic image onto a surrounding hemispherical viewing surface/screen where the viewer is positioned within the surrounding screen;

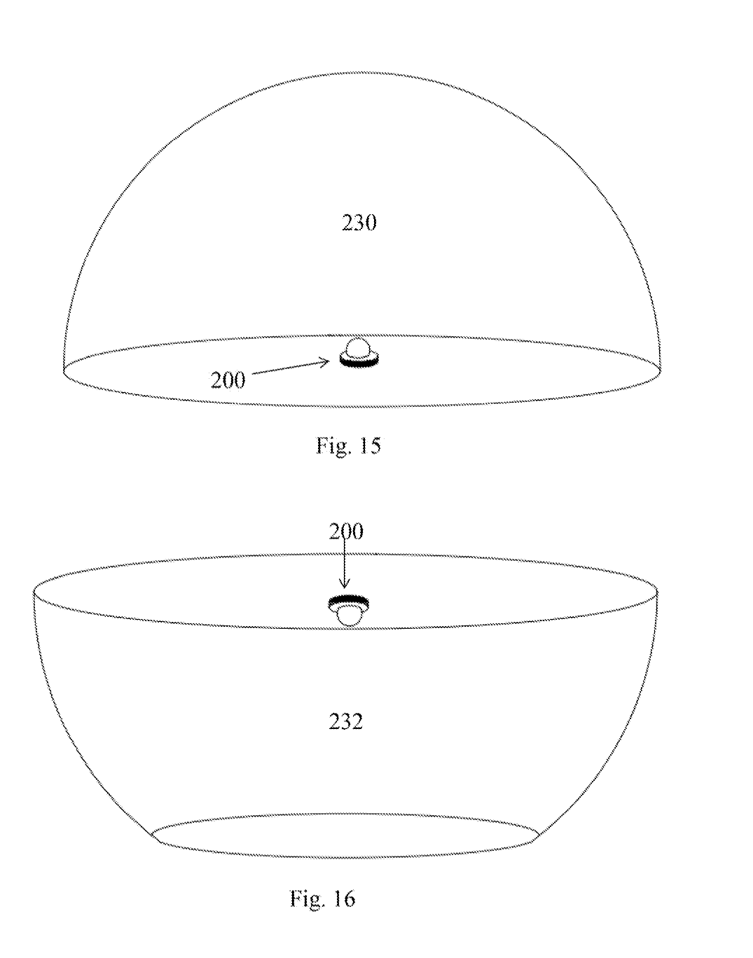

FIG. 16 illustrates a projector unit of any of FIGS. 12 to 14 positioned for projecting a panoramic image onto a surrounding hemispherical viewing surface/screen where the viewer is positioned within the surrounding screen and the projector is overhead;

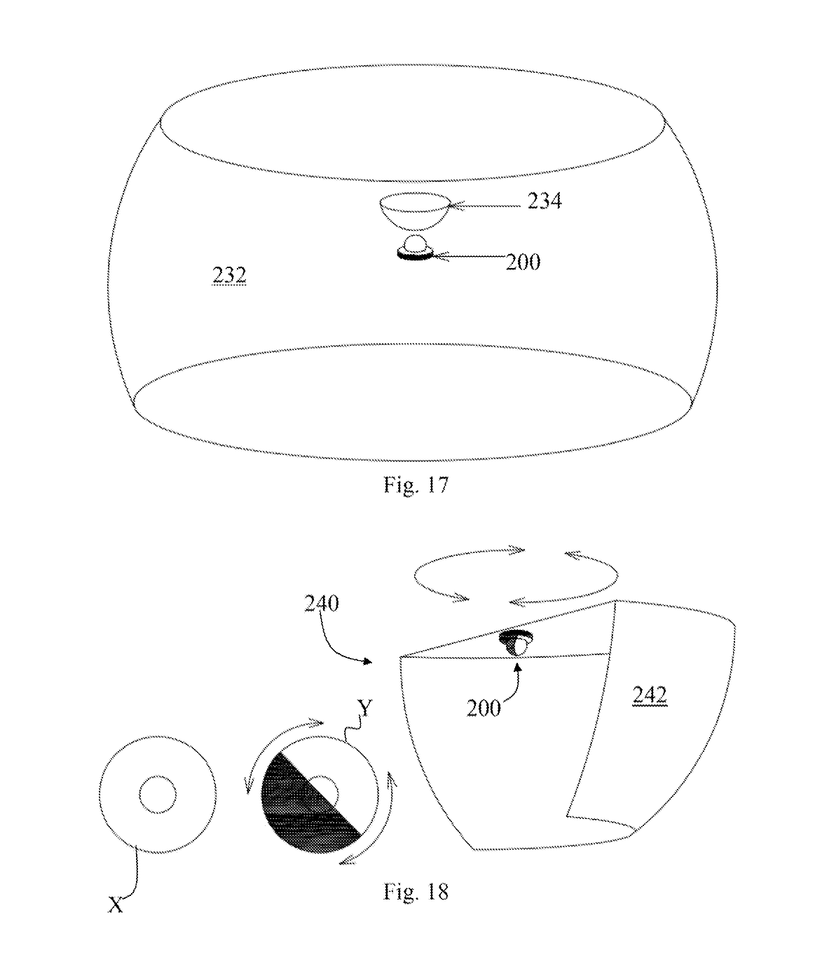

FIG. 17 shows a similar arrangement to that of FIG. 16, but with the projector unit mounted underneath and facing a hemispherical reflector element in order to project an inverted image onto a truncated hemispherical surrounding screen for viewing the projected image without the surrounding screen;

FIG. 18 is a perspective view of a projector system according to the invention comprise a heads-up display in the form of a headgear or the like worn by a user;

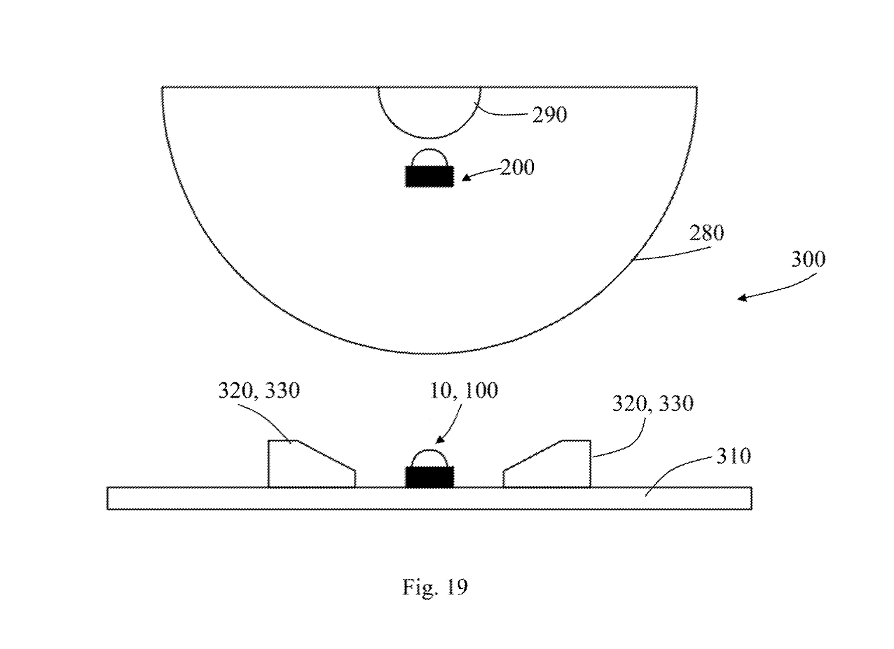

FIG. 19 is a schematic view of a conference station for a conference system employing a projector system according to the invention; and

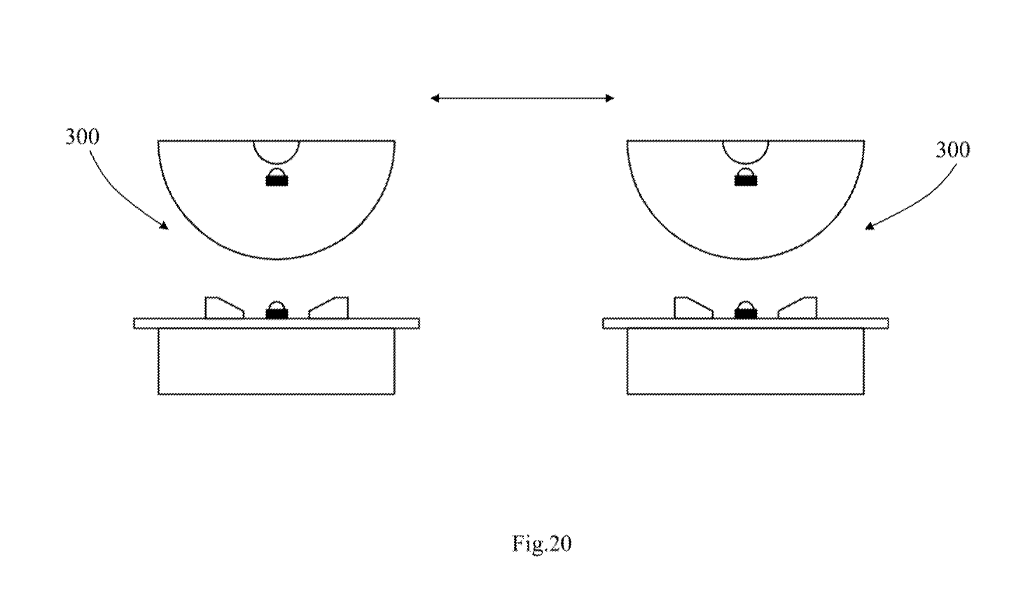

FIG. 20 is a schematic view of a conference system comprising a plurality of conference stations of FIG. 19.

### BEST MODE FOR CARRYING OUT THE INVENTION

### Best Mode

The following description is of preferred embodiments by way of example only and without limitation to the combination of features necessary for carrying the invention into effect.

In the following description, by very wide angle image is meant an image that is broader than a normal image view of a conventional camera unit, for example an image view equal to or exceeding 180 degrees around the camera unit. More particularly, this term is taken to refer to a substantially panoramic image view which may comprise a 360 degrees annular or doughnut shaped image view around the camera unit or a ‘full’ panoramic image view defining a generally hemispherical image field or vista about said camera unit.

Referring to FIG. 1, a first main embodiment of a first system according to the invention is shown. This embodiment comprises an integrated camera unit 10 comprising at least an image sensor 12 and means 14 for capturing a very wide angle image and directing it towards a photo-sensitive surface 16 of said image sensor 12.

The means 14 for capturing a very wide angle image and directing it towards a photo-sensitive surface 16 of the image sensor 12 may comprise any suitable system or arrangement known to the skilled artisan for capturing a wide angle image and focusing it onto an optical chip such as sensor 12. For example, the image capturing means 14 may comprise any one or any combination of: a lens, a set of lenses, a mirror, a set of mirrors, a prism, or a set of prisms. In this embodiment, the image capturing means comprises a hemispherical lens or a fish-eye lens 18. The fish-eye lens 18 captures a substantially panoramic image surrounding the camera unit 10. The substantially panoramic image may not be a full panoramic image, but preferably comprises a 360 degree doughnut shaped image view in a selected plane about the image capturing means 14. In most applications, a doughnut shaped image scene surrounding the camera unit 10 having a depth of about one third of the height of the hemispherical image scene is sufficient. However, in other applications, the substantially panoramic image is preferably a full panoramic image comprising the whole of the generally hemispherical image view surrounding the camera unit 10.

The image sensor 12 converts image light incident on its planar photo-sensitive surface 16 into one or more electrical signals. The image sensor 12 comprises a solid-state device such as an image sensor chip 12. The planar photo-sensitive surface 16 of the chip 12 comprises a plurality of photo sensors or pixels (not shown in FIG. 1) which each convert light incident thereon into an electrical or electronic signal or signals. Contrary to the view shown in FIG. 1b, the photosensitive surface 16 may not cover the whole of the upper surface of the chip 12, but may cover only that part of the chip's surface that underlies the image capturing means 14.

A number of optical chip types that could be employed as the image capturing means 14 are already known such as a charge-coupled device CCD) chip and a complementary metal oxide semiconductor (CMOS) chip. However, whilst a CCD chip is preferred for the camera unit 10 of this embodiment of the invention, as will be apparent to a skilled artisan, any chip suitable tor con vetting a captured image incident on a photo-sensitive surface thereof into an electrical signal or signals can be employed in the system and camera unit of the invention such as image sensors manufactured by Foveon?. However, as will be described below, certain novel modifications may be made to the chip for its use in the present invention.

One such modification is that the plurality of photo sensors or pixels of the image sensor chip 12 is arranged on the planar photo-sensitive surface 16 in a generally circular arrangement as opposed to a square grid array of rows and columns of photo sensors or pixels as is known in currently available CCD chips or the like. The choice of a generally circular arrangement is primarily to provide a pattern of photo sensors or pixels that most or more efficiently captures a received image incident thereon with less distortion than in conventional arrangements and/or requiring less processing to remove, reduce or correct any distortion, if present, of the image or a portion of the image for display on a conventional monitor display comprising horizontal lines. There are, however, a number of additional unexpected technical benefits arising from a generally circular arrangement of the photo sensors or pixels which will become apparent from the following description.

As shown in FIGS. 2a and b, in one embodiment of the camera unit 10 of the invention, the plurality of photo sensors or pixels 20 is arranged on said planar photo-sensitive surface 16 as a series of concentric circles of equal numbers of pixels 20. This is best seen in FIG. 2b where the radiating lines 22 radially intersect correspondingly positioned pixels 20 from the many concentric circles 24 of pixels 20. The concentric circles 24 of photo sensors or pixels 20 may occupy the whole of the photo-sensitive surface 16 of the image sensor chip 12. The pixels 20 may be sized and/or shaped such that there are no spaces between adjacent pixels 20, i.e. the photo sensors or pixels are contiguous.

In other arrangements as shown in FIG. 21, a central area 26 of the photo-sensitive surface 16 may have a reduced density of photo sensors or pixels 20 or may be absent any photo sensors or pixels 20 as would be appropriate for a camera unit providing a partial, rather than a ‘full’, panoramic image view. Alternatively, for a camera unit adapted to provide, a full panoramic image view, the central area 26 of the chip's photo-sensitive surface 16 may have a different pattern of photo sensors or pixels 20 to that of the surrounding area occupied by the concentric rings 24 of sensors or pixels 20 to account for the fact that it is difficult to implement the same size, shape and/or number of pixels in concentric rings 24 in the central region 26 as it is in the outer region of the photo-sensitive surface 16. In this embodiment, the number of photo sensors or pixels 20 in each concentric circle 2.4 is the same as for other concentric circles 24, but they may be of decreasing areas and/or of different shapes for inner circles 24 compared to outer circles 24.

As shown in FIGS. 3a and b, in another embodiment of the camera unit 10 of the invention, the plurality of photo sensors or pixels 20 is arranged on said photo-sensitive surface 16 as a series of concentric circles 24 of unequal numbers of pixels 20 to make accommodation for generally the same size sensors or pixels 20 in each concentric circle 24. Again, the central area 26 of the chip's photo-sensitive surface 16 may have no pixels or a different pattern of photo sensors or pixels 20 to that of the surrounding area occupied by the concentric rings 24 of sensors or pixels 20.

In yet other embodiments, the photosensitive surface 16 may be zoned so as to have an outer region of concentric circles with the same number of sensors or pixels as each other and an inner region having the same number of sensors or pixels as each other, but where the number of sensors or pixels in a concentric circle of the outer zone being different to that of a circle in the inner zone. It will be appreciated that zoning of the photo-sensitive surface 16 allows for different combinations of sensor or pixel numbers, shapes and/or sizes to be arranged in the concentric circles of the respective zones leading to the image sensor chip 12 providing different image effects such as image resolution per zone. It will also be appreciated that the photo-sensitive surface may have more than two zones including a central area zone 26 with a non-circular arrangement of sensors or pixels or no sensors or pixels.

Where the camera unit is capturing a moving image and the electrical signals representative of the captured moving image are converted to a digital format, said digital format may conveniently comprise a digital video format. This may be an interlaced or progressive digital video format. In the case of an interlaced digital video format, alternate ones of said series of concentric circles 24 of photo sensors or pixels 20 are respectively assigned to odd and even lines of the digital video signal. In the case of a progressive digital video format, all of the concentric circles 24 of sensors or pixels 20 are assigned to the progressive line of the digital video signal.

As shown in FIGS. 4a and b, in another embodiment of the camera unit 10 of the invention, the plurality of photo sensors or pixels 20 is arranged on the photo-sensitive surface 16 as comprising at least one tightly spiraled line of photo sensors or pixels 20. Again, the size and/or shape of the pixels 20 may be such that there are no spaces between adjacent or surrounding pixels. At first view, FIG. 4a appears to show the pixels 20 arranged in a series of concentric circles of equal numbers of pixels as shown in FIG. 2a, but, as best seen in FIG. 4b, the pixels 20 are arranged in a single spiraled line 28 of photo sensors or pixels 20 with the pixels 20 being radially aligned as illustrated by the radially extending lines 30 in FIG. 4b. Again, the central area 26 of the chip's photo-sensitive surface 16 may have no pixels or a different pattern of photo sensors or pixels 20 to that of the surrounding area occupied by the single spiraled line 28 of sensors or pixels 20.

Alternatively, as shown in FIGS. 5a and b, the pixels in the single spiraled line 28 of sensors or pixels 20 are not radially aligned as in FIGS. 4a and b, but are arranged to have a similar density throughout the area of the photosensitive surface 16 occupied by the single spiraled line 28 of sensors or pixels 20.

As shown in FIGS. 6a and b, the photosensitive area 16 comprises two interlaced tightly spiraled lines 32, 34 of photo sensors or pixels 20 having radially aligned pixels 20, but, depending on the camera application, there may be three or more interlaced tightly spiraled lines of photo sensors or pixels covering the photo-sensitive surface 16 of the image sensor chip 12. Again, the central area 26 of the chip's photo-sensitive surface 16 may have no pixels or a different pattern of photo sensors or pixels 20 to that of the surrounding area occupied by the two spiraled lines 32, 34 of sensors or pixels 20.

Alternatively, as shown in FIGS. 7a and b, the pixels in the two spiraled lines 32, 34 of sensors or pixels 20 are not radially aligned as in FIGS. 6a and b, but are arranged to have a similar density throughout the area of the photosensitive surface 16 occupied by the two spiraled lines 32, 34 of sensors or pixels 20.

One unexpected technical benefit of using one or more tightly spiraled lines of sensors or pixels is that it is possible to populate the photo-sensitive surface to a greater degree than by using concentric circles of sensors or pixels. In other words, although not shown in FIGS. 4 to 7, it is possible to have a much smaller central area having no sensors or pixels or a different pattern of sensors or pixels than is the case with concentric circles thereby improving image conversion to a digital format and thereby reducing the need for special processing of the central region of the image sensor chip surface.

The size and/or area of the pixels 20 forming the one or lines of spiraled sensors or pixels may be the same along the one or more lines or may progressively decrease in size and/or area as the lines nears the centre of the photo-sensitive surface.

A further unexpected technical advantage of using one or more spiraled lines is that, by ensuring that the spirals are tight, i.e. that corresponding portions of the spiral lines are positioned closely together such that there are no spaces between adjacent or surrounding pixels, the sensors or pixels are positioned in an arrangement that is only slightly offset compared to a concentric circle arrangement and yet form one or more progressive lines extending from the outer edge of the photo-sensitive surface to near its centre point.

Where the photo-sensitive surface comprises a single spiral of sensors or pixels, this can be assigned to a progressive line digital video signal. Where the photo-sensitive surface comprises two interlaced spirals of sensors or pixels, each line can be assigned to respective odd or even lines of a dual line digital video signal.

In the embodiments of FIGS. 2 to 7, the arrangement of lines of photo sensors or pixels and the shapes of the sensors or pixels may be such that said line or lines of photo sensors or pixels fills the surface of the photo-sensitive surface without leaving any gaps between said photo sensors or pixels. Furthermore, the photo sensors or pixels may comprise any of Bayer sensors, Foveon? sensors or CCD sensors, e.g. 3CCD sensors, as appropriate. A Bayer sensor is as low cost sensor and commonly found in image sensor chips. The Bayer sensor comprises a colour filter array that passes red, green, or blue light to selected pixel sensors, forming interlaced grids sensitive to red, green, and blue. The Bayer sensors also include back-illuminated sensors, where the light enters the sensitive silicon from the opposite side of where transistors and metal wires are, such that metal connections on the devices side are not an obstacle for the light, and the efficiency is higher. A Foveon sensor uses array of layered pixel sensors, separating light via the inherent wavelength-dependent absorption property of silicon, such that every location senses all three color channels. A 3CCD sensor uses three discrete image sensors, with the color separation done by a dichroic prism.

Whilst arranging the photo-sensors or pixels 20 in a generally circular arrangement offers the advantage that the distortion of the image caused by the fish-eye lens 18 is to some degree counter-acted by the arrangement of pixels thereby reducing processing of the digital image data for replay to account for any remaining distortions, the invention may include, for high quality applications, modifying the pattern of the photo-sensors or pixels 20 on the photosensitive surface 16 to ‘match’ the pattern to a specific lens 18, i.e. to modify the generally circular arrangement of pixels 20 such that the modified pattern substantially counteracts all distortion caused by said specific lens. The layout of pixels on the photosensitive surface is determined by a masking process that will be understood by a skilled artisan and it follows therefore that one can make a mask for a specific optical chip that is matched to a specific lens by patterning the light transmission characteristics of the lens. The modification of the pattern may include some of the modifications already alluded to such as the density, size, area, shape of the pixels. This may include increasing the density size, area and/or shape of pixels where the image is compressed by the lens and decreasing the density, size, area and/or shape where the image is expanded by the lens.

Notwithstanding the specific arrangement of the photo sensors or pixels on the photo-sensitive surface, the signal outputs of the sensors or pixels may be read or processed in a radial manner, namely the outputs of innermost sensors near to a central point or region of the photo-sensitive surface may be read first followed successively by the outputs of sensors or pixels positioned radially outwardly from said innermost sensors. Alternatively, the outmost sensors or pixels on the photo-sensitive surface may be read or processed first followed successively by the outputs of sensors or pixels positioned radially inwardly from said outermost sensors.

In another embodiment, the photo sensors or pixels of the photo-sensitive surface may be arranged to radially capture or scan a very wide angle image, e.g. to radially capture or scan a generally circular image.

Referring again to FIG. 1, the camera unit 10 may include means for converting electrical signals generated by said photo sensors or pixels 20 into digital image data. The means 40 for converting may comprise suitable circuitry provided in the camera unit as is known for CCD chips or additional circuitry on the image sensor chip itself as is known for CMOS chips. In any event, it is useful that the camera unit 10 in this embodiment includes circuitry for generating digital image data from an output of the image sensor chip 12, although it will be understood that, for some camera units, depending on their application or use, the camera unit may have an output for transmitting output signals from the image sensor chip 12 to a remote device (not shown) for conversion to digital image data at said remote device.

The integrated camera unit 10 thus far described with respect to FIGS. 1 to 7 may form a camera unit 10 in a system whereby the camera unit 10 outputs digital image data or signals representative of a captured panoramic image to one or more remote devices where further processing of the signals or data may be implemented. In such a system, the camera unit 10 operates to capture a panoramic image view and to convey data or signals representative of said image view to at least one of said remote devices for display and/or further processing. The camera unit 10 may be arranged to capture still images in the mariner of a stills images camera, but preferably it is arranged to capture moving images, although it preferable that it will also retain a still images capacity.

Also referring to FIG. 1, where the camera unit 10 does include means for converting electrical signals generated by said photo sensors or pixels into digital image data, it may also include means 40 for buffering, and/or storing said digital image data. Any suitable storage or buffering means 40 familiar to a skilled artisan may be used for buffering and/or storing the digital image data on the camera unit 10. For example, the means 40 for buffering or storing said digital image data may comprise a flash memory device or chip.

In this embodiment, the camera unit 10 includes an input means 42 such as a button, touch screen or the like for receiving a selection of a window portion of said captured panoramic image. The camera unit 10 also has a memory means 44 storing computer readable instructions which, when executed by a processor 46, controls the operations of the camera unit 10 including enabling a user to enter a selection of a window portion of the stored or buffered panoramic image via the input means 42. It will be understood that buffering digital image data enables real-time selection of a window portion of a viewed image scene whereas storing digital image data allows selection of a window portion of a previously recorded image scene.

Referring to FIG. 8, the selection of a window portion may comprise displaying an image 60 or a plan 62 of the panoramic image or a representative image 64 of the panoramic image with a window frame 66 overlying said display image, plan or representative image 60, 62, 64 on a display screen 48 of said camera unit 10 or a display screen of a peripheral device (not shown) connected to said camera unit 10. The position of the window frame 66 relative to the display image, plan or representative image 60, 62, 64 can be manipulated by a user as illustrated by armed lines 68, 70, 72 to move it over the display image, plan or representative image 60, 62, 64 to thereby select a desired window portion of the panoramic image for retrieval and display/playing. Of course, other methods of selecting a desired window portion may be provided depending on the nature and configuration of the input means 42.

In order to identify a selected window portion for retrieval, the photo sensors or pixels 20 of the image sensor chip 12 are preferably addressable or otherwise identifiable whereby, when a user inputs a selection of a desired window portion using the window frame 66, this is translated by the processor 46 of the camera unit 10 into addresses or identifiers for appropriate individual or blocks of photo sensors or pixels 20 and/or the lines they occupy in order to determine which digital image data is to be retrieved in response to a selected window portion.

The processor 46 also enables the retrieval from said buffer or storage means 40 of the digital data comprising said selected window portion and for further processing and/or display on the screen of said camera unit 10, or for said retrieved digital image data to be outputted on an output port 50 of the camera unit 10 to the peripheral device or a separate display device such as a personal computer, personal digital assistant, smart phone or the like.

Referring to FIG. 9, this illustrates the relationship between a selected window portion 74 of a panoramic image 73 captured by the camera unit 10 on an image sensor chip 12 having a concentric circle arrangement as hereinbefore described with respect to FIG. 2 or 3 and the display of such window portion 74 on the screen 48 of the camera unit 10 or a remote monitor of a PC, for example. It will be understood that none or a reduced amount of image data processing is required for displaying the selected window portion 74 on a conventional planar display device when compared with camera units employing image sensor chips with non-circularly arranged photo sensors or pixels.

It will be understood that the above method of selecting a desired window portion of a panoramic image captured by the camera unit 10 of the invention can equally be used with an image captured using an optical chip have an arrangement of pixels or photo-sensors according to any of FIGS. 4 to 7.

In the camera unit 10 of FIG. 1, the processor 46 may execute instructions to enable a user to choose an aspect ratio of the selected window portion. As illustrated in FIG. 10, the aspect ratio may be selected from a plurality of predefined aspect ratios A, B, C. Said predefined aspect ratios A, B, C may be defined with respect to the aspect ratios of the display screens of a number of conventional devices. Alternatively, the aspect ratio for a display window portion may comprise a user defined aspect ratio within predefined limits. In another alternative, the processor 46 may execute instructions to automatically select an aspect ratio of the camera unit's screen 48 or the aspect ratio of the screen of an attached remote display device as the aspect ratio of the requested window portion.

Referring now to FIG. 11, a second main embodiment of the first system according to the invention is shown. This comprises a distributed system including a camera unit 100 for capturing a panoramic image and outputting digital image data or electrical signals representative of said captured panoramic image to one or more separate devices including a memory bank or database 102, a server or controller 104, one or more input devices 106. The memory bank or database 102 is provided for storing and or buffering digital image data. The separate memory bank or database 102 may also be adapted to convert electrical signals received from the camera unit 100 representative of the panoramic image into digital image data in the case where the camera unit does not have this capability. The system includes the server or controller 104 for processing a selection or selections of requested window portions of the panoramic image from one or more users and retrieving digital image data in response to said selections, and the one or more input devices 106 are configured for sending requested selections of window portions of the panoramic image to the server or controller 104 and receiving for display or otherwise digital image data retrieved in response to issued requests.

The camera unit 100 employs an image sensor chip 12 as hereinbefore described with respect to the first main embodiment of the invention as described with respect to FIGS. 1 to 10. The camera unit 100 preferably includes means for converting the output of its image sensor chip to digital image data in a similar manner to the camera unit 10 of the first main embodiment, but this is not essential to the working of the system of the second main embodiment. The camera unit 100 may also include means for buffering or storing said digital image data locally, but preferably the storage of the digital image data is provided by the separate memory bank or database 102. Therefore, the camera unit 100 is connected to said memory hank or database 102 in a manner that enables said digital image data to be transmitted from said camera unit 100 to said memory hank or database 102, either in real-time by streaming data from said camera unit 100 to said memory bank or database 102 or not in real-time where data is transmitted in batches or as files, for example. The server/controller 104 and the one or more input devices 106 may also be connected to the memory bank or database 102 and/or the camera unit 100. The input devices 106 may comprise any suitable electronic device for receiving and displaying image data such as a PC, a personal digital assistant, as smart phone, as games player, a smart television, for example and without limitation.

Transmission of digital image data between devices and, more particularly from the camera unit 100 to the memory hank or database 102 may be in real time or performed by batches either on demand, by polling or by any other suitable transmission scheme. The camera unit 100 may be connected to the memory bank or database 102 by a cable, a cable network, or a communication network 108. The server/controller 104 and the input devices 106 may also be connected to the memory bank or database 102 and the camera unit 100 by cables, the cable network, or the communication network 108. The communication network 108 may be a private communication network, a public network, or a combination of the two. The network may include or comprise the Internet 110 as illustrated by the cloud in FIG. 11. It may also comprise or include a local area network (LAN) and/or as wide area network (WAN). A skilled artisan will appreciate the nature of networks that can be used to interconnect network enabled devices and, in the system of this embodiment, all of the separate, remote devices comprising the system are preferably network enabled for sharing data and/or command, request and response messages.

The system of FIG. 11 may comprise a surveillance system employing one or more camera units 10, 100 according to the invention, a public entertainment events distribution system also employing one or more camera units 10, 100, or a teleconferencing system by way of examples only.

In use, the camera unit 10, 100 of the distributed system of FIG. 11 captures a panoramic image and provides electrical signals or digital image data representing or defining said image to the memory bank or database 102 which is preferably a network accessible database for buffering and storing digital image data.

The server/controller 104 is arranged to process requests from user devices 106. These requests may comprise or include user requested selected window portions of the panoramic image. The requests may be for window portions of a real time image scene or of a previously recorded image scene. In any case, the server/controller 104 acts to communicate with the database 102 to retrieve digital image data in response to said requests and to transmit retrieved data to the respective input devices 106. The server/controller 104 may also receive and process control commands related to requested selections from user devices 106 and modify data retrieval from the database accordingly.

The system of FIG. 11 enables a user of an input device 106 such as a control point of a surveillance system, an editing point of a TV production system, an end user's TV, a PC, a PDA or mobile handset or the like to request a portion of a panoramic image for display or further processing at their input device 106 and to issue commands related to requested selections of window portions.

Referring again to FIG. 10, illustrated is the display image, plan or representative image 60, 62, 64 of the captured panoramic image 73 which conforms to the layout of the camera unit's image sensor photo-sensitive surface 16. Window portions A, B, C of predefined aspect ratios are marked on the plan of the panoramic image 73 by way of example with these being matched to specific types of user input device. However, it is not essential that the aspect ratios are either predefined or matched to any particular device although some benefits are achieved by doing so.

As illustrated in FIG. 10, a user may issue a number of commands in connection with their selection of a window portion of the panoramic image 73. In this example, the commands comprise panning commands 70, 72 whereby the user is requesting that the selected window portion is panned around the image 73. Other commands include a tilt command 68 which would result in the selected window portion migrating towards the centre of the plan view of FIG. 10 or a zoom-in or zoom-out feature which would render a larger or smaller representation of the selected window portion.

The server/controller 104 can accept multiple requests from multiple users such that users' requested window portions may overlap, for example. Furthermore, each of the users may actively change their selected window portion through the above mentioned commands which may comprise real-time commands allowing the user to view any part of the captured panoramic image 73.

In a surveillance system using one or more camera units 10, 100 according to the invention and a memory device 40, 102 for buffering and/or storing digital image data, security operatives at control points could use the image captured by a single camera unit 10, 100 to survey or monitor a panoramic area around said camera unit 10, 100 thereby negating the need for a plurality of conventional camera units to cover the same area. Furthermore, as each of the operatives can issue commands such as pan, tilt and zoom, the camera unit in the system of the invention negates the need to provide conventional camera units with motors to effect physical panning and tilting actions or to assign certain cameras to certain operatives as in conventional systems.

Also in surveillance systems, even if a security operative has failed to see an activity occur in real time out of view of the security operative's selected window portion, the storage of the panoramic image enables later review of the panoramic image to review said missed activity for evidence and/or other security purposes.

In a public entertainment distribution system, users 106 subscribing or otherwise connecting to a digital rights owner's system (represented by the server controller 104 in FIG. 11) for viewing images of a concert, for example, would be free to observe any portion of the panoramic image and not rely on a production director to dictate the images being made available to viewers. This freedom to self-edit what is being viewed greatly enhances the desirability to subscribe to or buy access to the digital rights owner's content. Furthermore, a user could create a unique viewing experience each time he/she views a concert or public entertainment event recorded in panoramic image mode.

It can be seen that in one aspect the invention concerns a solid state camera system designed to offer multiple users the ability to explore a remote location both live or pre recorded with discrete real-time control of pan, tilt and zoom functions within a 360 degree vista. The device consists of a hemispherical or fisheye lens mounted on an optical sensor chip such as a CCD capturing a full 360 degree vista of it's surrounding environment.

The resultant image hitting the sensor array is circular and assuming the device is set in the horizontal plane, the main area of interest in most applications would be the panorama of the horizontal field of view which would be located in a doughnut shaped area of the circle from its outer edge to approximately one third of its diameter.

The output of the sensor array is fed into a buffer, a subset or ‘window’ of which is then outputted to the user at the appropriate resolution and aspect ratio of the user's monitor device. The user can then control the movement of the window within the display buffer to select in which direction they wish to see thus enabling multiple users to control discrete pan and tilt parameters within the 360 degree vista at any required resolution and aspect ratio simultaneously. Whilst the full vista output of the device may not be seen in it's entirety, it can be recorded and interrogated later with the freedom to pan & tilt anywhere within the 360 degree vista captured by the device.

Referring now to FIG. 12, a first main embodiment of a second system according to the invention is shown. The system comprises a system for projecting a very wide angle image onto a viewing surface (not shown). The system comprises a projector unit 200 having means such as an input 202 for receiving very wide angle image data. The projector unit 200 also has means 204 for converting said very wide angle image data into an optical image. In this embodiment, said converting means 204 comprises an optical chip or array 206 of light emitting photo-sensors or pixels 205. These are arranged in a generally circular pattern in like manner to the patterns of the photo sensors or pixels of the optical chip 12 shown in FIGS. 2 to 7 including having alternate concentric circles of light emitting elements 205 assigned thereto odd and even lines of a digital video signal embodied in received digital image data, for example. In effect, the light emitting photo-sensors or pixels 205 of the projector unit 200 perform the reverse operation of the pixels of the optical chip 12 of the first system of the invention in that the light emitting photo-sensors or pixels 205 convert electrical signals derived from the received optical image data into light. The optical chip or array 206 of light emitting photo-sensors or pixels 205 is arranged to direct emitted light comprising an optical image or a portion of said optical image towards an image projection means 208. A viewing surface such as a screen or visor or the like (not shown) may be mounted in proximity to said image projection means 208 wherein said image projection means 208 projects said optical image or a portion thereof onto said viewing surface. In some embodiments, the light emitting photo-sensors or pixels 205 may comprise light emitting diodes (LEDs) liquid crystal display (LCD) elements.

The projector unit 200 may include buffer or stage means 210 for buffering and/or storing received digital image data embodying a panoramic image (still or moving), a memory means 212 for storing machine executable instructions and a processor 214 for executing said instructions to process received digital image data and convert it to electrical signals as an input to the converting means 204 as well as to control other actions and applications of the projector unit 200. Alternatively, the projector unit 200 may be connected to a buffer/storage means such as a database over a communications network whereby digital image data is transmitted to the projector unit 200 from said database over the network. Thus, the projector unit may comprise part of the first system of the invention as shown in FIG. 11 whereby digital images captured by a camera unit 10, 100 are transmitted to the database 102 and are subsequently transmitted to the projector unit 200 upon request or by some other trigger action.

In use, the received digital image data may be received at the projector unit 200 directly from the camera unit 10, 100 or from the database 102 of the distributed system of FIG. 11, for example.

In like manner to the first system of the invention, the image projection means 206 may comprise a lens, a set of lenses, a mirror, a set of mirrors, a prism, or a set of prisms for projecting the optical image generated by said plurality of photo sensors or pixels, but in the embodiment of FIG. 12, the image projection means 206 comprises a fish-eye lens 216. The fish-eye lens may be matched to the light emitting chip or array 206 to reduce or eliminate distortions on projection of the image onto the viewing surface.

Also in a like manner to the first system of the invention, the second system of the invention may include an input means 218 for receiving a selection of a window portion of said very wide angle optical image whereby the processor 214 is arranged to then retrieve digital image data comprising said selected window portion from the buffer or storage means 210 or from the database (FIG. 11). Thus, in operation, a user may select a window portion of a panoramic image via a windowed display 220 on the projector unit 200 or a connected device (now shown) showing a window frame to enable a user to select a portion of the panoramic image which is then projected onto the viewing surface, e.g. a display screen. The means for receiving a selection of a window portion of said very wide angle image may be adapted to receive commands associated with said selected window portion such as any of a pan command, a tilt command and a room command.

The means for receiving a selection of a window portion of said very wide angle image may also comprise the server/controller 104 of FIG. 11 and the server/controller 104 may be arranged to also retrieve digital image data comprising said selected window portion from the database 102 for onward transmission to the projector unit 200.

Referring now to FIG. 13, a second main embodiment of the second system according to the invention is shown. This has generally the same structure as the first main embodiment of the second system shown in FIG. 12 except that the plurality of light emitting pixels is replaced by a LED or LCD type display panel 222 with a backlight 224 or the like.

Referring now to FIG. 14, a third main embodiment of the second system according to the invention is shown. This has generally the same structure as the first main embodiment of the second system shown in FIG. 12 except that the plurality of light emitting pixels is replaced by a laser 226 scanning a generally circular array provided on a scanning mirror 228.

FIG. 15 illustrates a projector unit of any of FIGS. 12 to 14 positioned for projecting a panoramic image onto a surrounding hemispherical viewing surface/screen 230 where the viewer is positioned within the surrounding screen 230. In this arrangement, the full panoramic image may be projected onto the screen 230 or selected portions projected onto corresponding or selected portions of the surrounding screen.

FIG. 16 shows a similar arrangement to that of FIG. 15, but with the projector unit 200 mounted overhead the substantially hemispherical surrounding screen 232 which is inverted when compared to the arrangement of FIG. 15. Again, the full panoramic image may be projected onto the screen 232 or selected portions projected onto corresponding or selected portions of the surrounding screen.

FIG. 17 shows a similar arrangement to that of FIG. 16, but with the projector unit 200 mounted underneath and facing a hemispherical reflector element 234 in order to project an image onto the truncated hemispherical surrounding screen 236 which is also inverted when compared to the arrangement of FIG. 15. Again, the full panoramic image may be projected onto the screen or selected portions projected onto corresponding portions of the surrounding screen. In this case, the arrangement may be that the projected image is viewed from outside the screen 232 rather than from within it.

As shown in FIG. 18, the second system according to the invention may comprise a heads-up display in the form of a headgear 240 worn by a user. The viewing surface may therefore comprise a visor 242 of the headgear 240 whereby a portion of a panoramic image is projected onto an inner surface of the visor 242 for viewing by the person wearing the headgear. In this arrangement, the full panoramic image represented by X in FIG. 18 captured by a camera 10, 100 is made available to the headgear 240 or an information processing unit (not shown) associated with the headgear. However, only a portion of the full image as represented by Y in FIG. 18 is projected onto the visor by a partial fish-eye projector unit 200. The arrangement of the headgear is such that the information processing unit receives a selection of a window portion of said very wide angle optical image in response to movement of the person's head and thus the headgear relative to a predetermined datum. The predetermined datum is taken as a point or line representing a middle point of as person's forward view relative to their body position. Thus, the panoramic image made available to the information processing system comprises or represents a panoramic view around the person wearing the headgear. As the person rotates their head awn from the selected datum, the image displayed in the visor rotates to match the view that the person would naturally see if they were directly viewing the image around themselves. An advantage of this arrangement is that it does not require the user to actually have a direct line of vision to any part of the panoramic view. In fact, the person may be in an enclosed environment where there is no possible direct image view of the panoramic view being viewed.

The headgear as depicted in FIG. 18 is also applicable to situations where the wearer of the headgear is not present at the centre-point of the surrounding image view, but is controlling a vehicle, e.g. an aircraft, that is at the centre of said image view. In this case, the remote located operator of the vehicle can see all around the vehicle through appropriate head movement being translated into new image view portions being projected onto the visor.

In yet another variation of this arrangement, the visor or viewing screen may not form part of the headgear, but may comprise a partially surrounding screen showing a portion of the panoramic image. However, as the operator moves their head, the portion of the panoramic image being projected onto the screen scrolls to a portion that is related to the operator's head position relative to the predetermined datum.

FIGS. 19 and 20 illustrate a conference call system according to the invention. FIG. 19 shows a conference call station 300 whilst FIG. 20 shows a plurality of conference call stations 300, each employing a camera unit 10, 100 according to the first system of the invention and a projector unit 200 according to the second system of the invention. In this embodiment of a conference call system, the camera unit 10, 100 is mounted generally centrally of a desk or conference table 310 and includes speakers/microphones 320/330 to enable participants to see, speak to and hear each other. Above each conference table 310 is a projector unit 200 with viewing screen 280 whereby conference call attendees may view from an outside surface of said screen 280 a panoramic image of the other conference station 300 projected onto an inside surface of the screen 280 via a hemispherical reflector 290.

In general, the invention provides an optical device such as a camera having an image sensor and a lens/mirror system or the like for capturing a very wide angle image such as a panoramic image and directing it towards a photo-sensitive surface of the image sensor. The image sensor converts the captured image, which may be a moving image, into an electrical signal. The image sensor has a plurality of photo sensors or pixels arranged on a photo-sensitive surface thereof in a generally circular arrangement. The generally circular arrangement may comprise a tight spiral of photo sensors or pixels. The plurality of photo sensors or pixels is addressable or identifiable such that a window portion of a captured image can be defined by references to addresses or identifiers of respective photo sensors or pixels. The camera may form part of an integrated or distributed system including means for converting said electrical signal into digital image data and means for buffering or storing said digital image data. The system may also include input means for receiving a selection of a window portion of said very wide angle image and means for retrieving digital image data comprising said selected window portion from said buffer or storage means and transmitting said retrieved digital image data to an information processing means for display and/or further processing. An optical device such as a projector unit utilizing a circular arrangement of light emitting elements for projecting a panoramic or partial panoramic image is also provided.

While the invention has been illustrated and described in detail in the drawings and foregoing description, the same is to be considered as illustrative and not restrictive in character, it being understood that only exemplary embodiments have been shown and described and do not limit the scope of the invention in any manner. It can be appreciated that any of the features described herein may be used with any embodiment. The illustrative embodiments are not exclusive of each other or of other embodiments not recited herein. Accordingly, the invention also provides embodiments that comprise combinations of one or more of the illustrative embodiments described above. Modifications and variations of the invention as herein set forth can be made without departing from the spirit and scope thereof, and, therefore, only such limitations should be imposed as are indicated by the appended claims.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

It is to be understood that, if any prior art publication is referred to herein, such reference does not constitute an admission that the publication forms a part of the common general knowledge in the art.

1-22. (canceled)

23. An image sensor for an optical device, said image sensor comprising:
a planar photo-sensitive surface comprising a plurality of photo sensors or pixels positioned on said planar photo-sensitive surface in a generally circular arrangement for converting an image incident thereon into an electrical or electronic signal or signals.

24. The image sensor of claim 23, wherein the plurality of photo sensors or pixels is arranged on said planar photo-sensitive surface as a series of concentric circles.

25. The image sensor of claim 23, wherein the plurality of photo sensors or pixels is arranged on said planar photo-sensitive surface in said generally circular arrangement comprising at least one spiral line of photo sensors or pixels.

26. The image sensor of claim 25, wherein the plurality or photo sensors or pixels is arranged on said planar photo-sensitive surface in said generally circular arrangement comprising two or more interlaced spiral lines of photo sensors or pixels.

27. The image sensor of claim 23, wherein said image sensor comprises means for capturing a very wide angle image and directing it towards said planar photo-sensitive surface to be incident on said plurality of photo sensors or pixels.

28. The image sensor of claim 27, wherein the means for capturing a very wide angle image is arranged to capture a substantially panoramic image surrounding the image sensor.

29. The image sensor of claim 28, wherein the substantially panoramic image is not a full panoramic image, but comprises a 360 degree doughnut shaped image view in a selected plane about the image sensor.

30. The image sensor of claim 28, wherein the substantially panoramic image is a full panoramic image comprising a generally hemispherical image view about the image capturing means.

31. The image sensor of claim 23, wherein said image sensor further comprises:
means for converting said electronic or electrical signal or signals into digital image data.

32. The image sensor of claim 23, wherein said plurality of photo sensors or pixels are addressable such that a window portion of a captured image can be defined by reference to addresses of respective photo sensors or pixels.

33. The image sensor of claim 23, wherein said optical device comprises a camera or a projector.

34. A system for capturing and recording a very wide angle image, comprising:
means for capturing a very wide angle image and directing it towards a planar photo-sensitive surface of an image sensor, said planar photosensitive surface comprising a plurality of photo sensors or pixels, said image sensor converting said very wide angle image into an electrical or electronic signal or signals;
means for converting said electrical or electronic signal or signals into digital image data;
means for buffering or storing said digital image data;
means for receiving a selection of a window portion of said very wide angle image; and
means for retrieving digital image data comprising said selected window portions of said very wide angle image from said buffer or storage means and transmitting said retrieved digital image data to an information processing means.

35. The system of claim 34, wherein the image sensor comprises the image sensor of claim 1.

36. A method of capturing and recording a very wide angle image, comprising the steps of:
capturing a very wide angle image and directing it towards a planar photo-sensitive surface of an image sensor, said planar photosensitive surface comprising a plurality of photo sensors or pixels;
converting said captured very wide angle image into an electrical or electronic signal or signals;
converting said electrical or electronic signal or signals into digital image data;
buffering or storing said digital image data;
receiving a selection of a window portion of said very wide angle image;
retrieving digital image data comprising said selected window portion of said very wide angle image from said buffer or storage means; and
transmitting said retrieved digital image data to an information processing means.
